(19) United States
(12) Patent Application Publication
(10) Pub. No.: US 2015/0313044 A1
(43) Pub. Date: Oct. 29, 2015

(54) ELECTROMAGNETIC SHIELDING MATERIAL AND CLOTHING USING THE SAME

(71) Applicant: Beijing FUNATE Innovation Technology Co., Ltd., Beijing (CN)

(72) Inventors: YU-QUAN WANG, Beijing (CN); LI QIAN, Beijing (CN)

(21) Appl. No.: 14/693,899

(22) Filed: Apr. 23, 2015

(30) Foreign Application Priority Data
Apr. 23, 2014 (CN) 201420199680.X

(51) Int. Cl. H05K 9/00; D04C 1/06; A41D 31/00

(52) U.S. Cl. CPC H05K 9/009; A41D 31/0094; D04C 1/06

(57) ABSTRACT

An electromagnetic shielding material including a substrate and a shield layer. The shield layer includes a carbon nanotube composite wire. The carbon nanotube composite wire includes a carbon nanotube wire and a metal layer. The carbon nanotube wire comprises a plurality of carbon nanotubes spirally arranged along an axial direction of the carbon nanotube wire. A twist of the carbon nanotube wire ranges from 10 r/cm to 300 r/cm. A diameter of the carbon nanotube wire ranges from 1 micron to 30 microns. A thickness of the metal layer ranges from 1 micron to 5 microns. Electromagnetic shielded clothing is also provided.

### CROSS-REFERENCE TO RELATED APPLICATIONS

This application claims all benefits accruing under 35 U.S.C. §119 from China Patent Application No. 201420199680.X, field on Apr. 23, 2014 in the China Intellectual Property Office, disclosure of which is incorporated herein by reference. The application is also related to copending applications entitled, “BINDING WIRE AND SEMICONDUCTOR PACKAGE STRUCTURE USING THE SAME”, filed ______ (Atty. Docket No. US56061); “CARBON NANOTUBE COMPOSITE WIRE”, filed ______ (Atty. Docket No. US56063); “HOT WIRE ANEMOMETER”, filed ______ (Atty. Docket No. US56064); “DEFROSTING GLASS, DEFROSTING LAMP AND VEHICLE USING THE SAME”, filed ______ (Atty. Docket No. US56065); “WIRE CUTTING ELECTRODE AND WIRE CUTTING DEVICE USING THE SAME”, filed ______ (Atty. Docket No. US56066); “CONDUCTIVE MESH AND TOUCH PANEL USING THE SAME”, filed ______ (Atty. Docket No. US56067); “MASS FLOWMETER”, filed ______ (Atty. Docket No. US56069).

### FIELD

The disclosure generally relates to an electromagnetic shielding material, and clothing using the electromagnetic shielding material.

### BACKGROUND

Studies have shown that long-term, excessive electrostatic and electromagnetic radiation will cause direct damage to human reproductive system, nervous system and immune system, which is the major cause of cardiovascular disease, diabetes and cancer. Long-term, excessive electrostatic and electromagnetic radiation can directly affect the growth of body tissues and bone in children. Additionally, long-term, excessive electrostatic and electromagnetic radiation can also cause a decline of vision, memory and liver hematopoiesis. Electrostatic radiation and electromagnetic radiation have become a fourth major pollution following air pollution, water pollution and noise pollution. As such, a protection from the electrostatic and electromagnetic radiation becomes urgent.

### BRIEF DESCRIPTION OF THE DRAWING

Implementations of the present technology will now be described, by way of example only, with reference to the attached figures.

FIG. 1 is a cross-sectional schematic of one embodiment of an electromagnetic shielding material.

FIG. 2 is a structure schematic of one embodiment of an untwisted carbon nanotube wire.

FIG. 3 is a structure schematic of one embodiment of a twisted carbon nanotube wire.

FIG. 4 shows a scanning electron microscope (SEM) image of one embodiment of a carbon nanotube composite wire.

FIG. 5 shows a tensile stress curve of the carbon nanotube composite wire in FIG. 4.

FIG. 6 is a structure schematic of a shield of the electromagnetic shielding material in FIG. 1.

FIG. 7 shows a SEM image of one embodiment of a drawn carbon nanotube film.

FIG. 8 shows a SEM image of one embodiment of a flocculated carbon nanotube film.

FIG. 9 shows a SEM image of one embodiment of a pressed carbon nanotube film.

FIG. 10 is a schematic view of one embodiment of an apron made of the electromagnetic shielding material.

FIG. 11 is a schematic view of one embodiment of a coat made of the electromagnetic shielding material.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

Several definitions that apply throughout this disclosure will now be presented.

The term “substantially” is defined to be essentially conforming to the particular dimension, shape, or other feature that the term modifies, such that the component need not be exact. For example, “substantially cylindrical” means that the object resembles a cylinder, but can have one or more deviations from a true cylinder. The term “comprising,” when utilized, means “including, but not necessarily limited to”; it specifically indicates open-ended inclusion or membership in the so-described combination, group, series and the like.

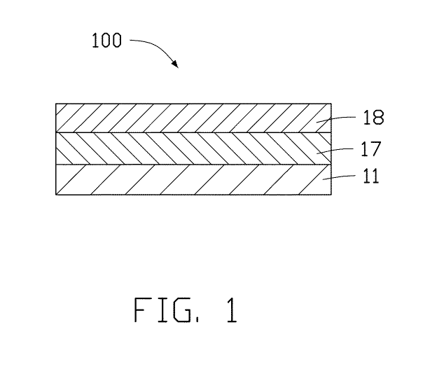

FIG. 1 illustrates a first embodiment of an electromagnetic shielding material 100 includes a substrate 11 and a shield layer 12. The shield layer 12 is located on at least one surface of the substrate 11.

The substrate 11 can be made of cotton, hemp, fiber, nylon, spandex, polyester, polyacrylonitrile, wool, silk, and the like. The fiber includes carbon fiber, chemical fiber, rayon, and so on. In one embodiment, the substrate 11 is made of rayon.

The substrate 11 is used to support the shield layer 12. The substrate 11 and the shield layer 12 can be sewn together or bonded together with an adhesive. In one embodiment, a waterproof adhesive can be used, thereby allowing washing of the electromagnetic shielding material 100 without degrading the bond.

The shield layer 12 includes a carbon nanotube structure; the carbon nanotube structure includes a plurality of carbon nanotubes forming a conductive closed circuit. Because carbon nanotubes have excellent conductivity, when a part of carbon nanotubes of the conductive closed circuit cuts magnetic induction lines in a magnetic field, a magnetic flux of the conductive closed circuit will be changed, and an induction electromotive force and an induced current will be produced in the electrically conductive closed circuit, thereby producing a reverse electromagnetic field for shielding the external magnetic field.

Since the carbon nanotubes have excellent conductivity, when an electric field intensity of a surface of the conductive closed circuit exceeds a critical value, original ions in air will have sufficient kinetic energy. The original ions can impact uncharged molecules in air and make them ionize, which can make the air partially conductive; thereby producing a corona discharge. The corona discharge can eliminate external charge, thereby achieving an anti-radiation and anti-static effect. Additionally, the carbon nanotubes have excellent conductivity, which can reduce a surface resistivity of the substrate 11 by forming a conductive layer on the surface of the substrate 11; thus electrostatic charge that has been generated can be quickly discharged, thereby improving the anti-radiation and anti-static effect.

A plurality of holes can be formed between the plurality of carbon nanotubes of the carbon nanotube structure. In one embodiment, a size of the holes is less than a quarter of a wavelength of an electromagnetic wave. In one embodiment, the size of the holes ranges from about 20 nm to about 400 nm.

The carbon nanotube structure includes at least one carbon nanotube wire, at least one carbon nanotube composite wire, at least one carbon nanotube film, and/or at least one carbon nanotube composite film. The arrangement of the carbon nanotube wire, the carbon nanotube composite wire, the carbon nanotube film, and the carbon nanotube composite film are not limited, as long as the carbon nanotube structure form a conductive closed circuit.

The carbon nanotube wire can be an untwisted carbon nanotube wire or a twisted carbon nanotube wire.

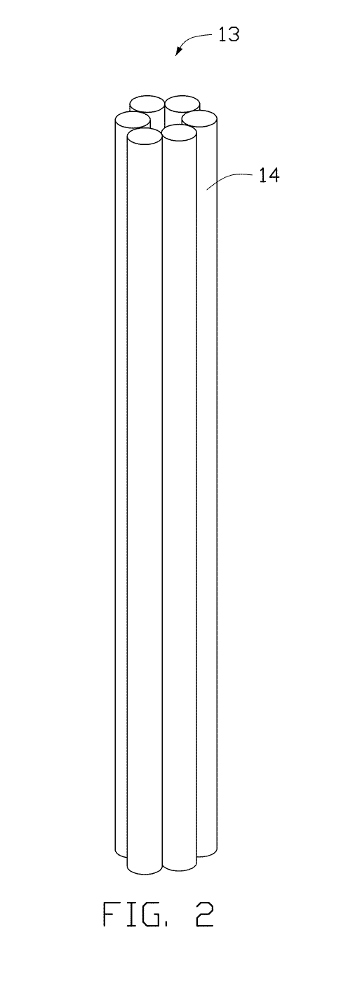

FIG. 2 illustrates that in one embodiment the carbon nanotube wire is the untwisted carbon nanotube wire 13. The untwisted carbon nanotube wire 13 includes a plurality of carbon nanotubes 14 substantially oriented along a length of the untwisted carbon nanotube wire 13. The untwisted carbon nanotube wire 13 can be formed by treating a drawn carbon nanotube film with a volatile organic solvent. The drawn carbon nanotube film can be formed by drawing a film from a carbon nanotube array; the drawn carbon nanotube film is capable of being a free-standing structure. The drawn carbon nanotube film includes a plurality of carbon nanotube segments joined end-to-end by van der Waals force. Each carbon nanotube segment includes a plurality of carbon nanotubes substantially parallel to each other, and combined by van der Waals force. A length of the untwisted carbon nanotube wire 13 can be set as desired. A diameter of the untwisted carbon nanotube wire 13 can range from about 0.5 nanometers to about 100 micrometers. The drawn carbon nanotube film is treated by applying an organic solvent to the drawn carbon nanotube film to soak the entire surface of the drawn carbon nanotube film. After being soaked by the organic solvent, the adjacent parallel carbon nanotubes in the drawn carbon nanotube film will bundle together when the organic solvent volatilizes, due to the surface tension of the organic solvent, and thus, the drawn carbon nanotube film will be shrunk into the untwisted carbon nanotube wire 13. The organic solvent can be volatile organic solvents, such as ethanol, methanol, acetone, dichloroethane, or chloroform. Compared with the drawn carbon nanotube film, a specific surface area of the untwisted carbon nanotube wire 13 will decrease, and a viscosity of the untwisted carbon nanotube wire 13 will increase.

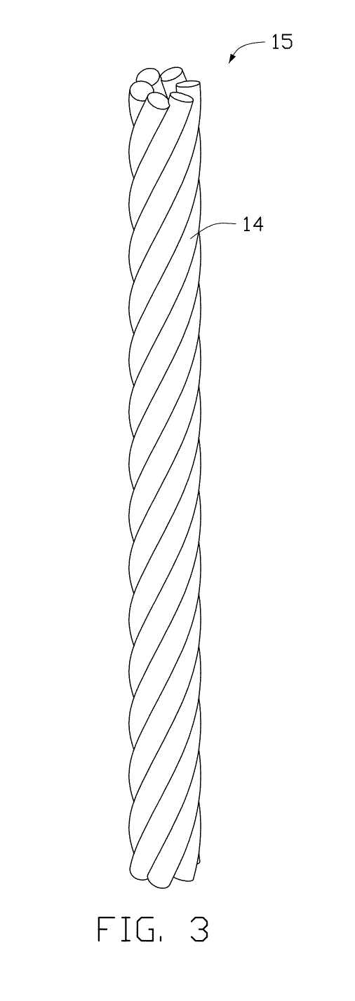

FIG. 3 illustrates that in one embodiment the carbon nanotube wire is the twisted carbon nanotube wire 15. The twisted carbon nanotube wire 15 includes a plurality of carbon nanotubes 14 spirally arranged along an axial direction of the twisted carbon nanotube wire 15. The twisted carbon nanotube wire 15 is formed by twisting a carbon nanotube film. The carbon nanotube film can be drawn from the carbon nanotube array. The carbon nanotube film includes a plurality of carbon nanotubes parallel with each other. The plurality of carbon nanotubes in the carbon nanotube film are substantially oriented along an axial direction of the carbon nanotube film, and joined end-to-end by van der Waals force in the axial direction of the carbon nanotube film. Therefore when the carbon nanotube film is twisted, the plurality of carbon nanotubes in the twisted carbon nanotube wire 15 are spirally arranged along the axial direction, in an end to end arrangement by van der Waals forces, and extends in a same direction.

In one embodiment, the twisted carbon nanotube wire 15 has an S twist or a Z twist. During the twisting process of the carbon nanotube film, a space between adjacent carbon nanotubes becomes smaller along a radial direction of the twisted carbon nanotube wire 15, and a contact area between the adjacent carbon nanotubes becomes larger along the radial direction of the twisted carbon nanotube wire 15. Therefore, van der Waals attractive force between adjacent carbon nanotubes along the radial direction of the twisted carbon nanotube wire 15 significantly increases, and adjacent carbon nanotubes in the twisted carbon nanotube wire 15 are closely connected. In one embodiment, the space between adjacent carbon nanotubes along the radial direction of the twisted carbon nanotube wire 15 is less than or equal to 10 nanometers. In one embodiment, the space between adjacent carbon nanotubes along the radial direction of the twisted carbon nanotube wire 15 is less than or equal to 5 nanometers. In one embodiment, the space between adjacent carbon nanotubes along the radial direction of the twisted carbon nanotube wire 15 is less than or equal to 1 nanometer. Since the space between adjacent carbon nanotubes in the radial direction of the twisted carbon nanotube wire 15 is small, and adjacent carbon nanotubes are closely connected by van der Waals force, the twisted carbon nanotube wire 15 includes a smooth and dense surface.

A diameter of the twisted carbon nanotube wire 15 can be set as desired. In one embodiment, the diameter of the twisted carbon nanotube wire 15 ranges from about 1 micron to about 30 microns. A twist of the twisted carbon nanotube wire 15 can range from about 10 r/cm to about 300 r/cm. The twist of the twisted carbon nanotube wire 15 refers to the number of turns per unit length of the twisted carbon nanotube wire 15. When the diameter of the twisted carbon nanotube wire 15 is constant, an appropriate twist can give the twisted carbon nanotube wire 15 excellent mechanical properties. Such as when the diameter of the twisted carbon nanotube wire 15 is less than 10 microns, the twist of the twisted carbon nanotube wire 15 ranges from about 250 r/cm to about 300 r/cm. When the diameter of the twisted carbon nanotube wire 15 ranges from about 10 microns to about 20 microns, the twist of the twisted carbon nanotube wire 15 ranges from about 200 r/cm to about 250 r/cm. When the diameter of the twisted carbon nanotube wire 15 ranges from about 25 microns to about 30 microns, the twist of the twisted carbon nanotube wire 15 ranges from about 100 r/cm to about 150 r/cm. The mechanical strength of the twisted carbon nanotube wire 15 is 5 to 10 times stronger than the mechanical strength of a gold wire of equal diameter.

The carbon nanotube composite wire can be formed by composite of the carbon nanotube wire with metal, polymer, non-metal, or other materials.

The metal layer 16 can improve a conductivity of the shield layer 12, and make the shield layer 12 produce a large induced current when penetrated by a magnetic field. Additionally, the metal layer 16 can improve the corona discharge of the shield layer 12, increase the neutralization of the external charge, and reduce the surface resistivity of the substrate 11. Thus, coating the metal layer 16 on the outer surface of the carbon nanotube wire can improve a radiation efficiency of the shield layer 12.

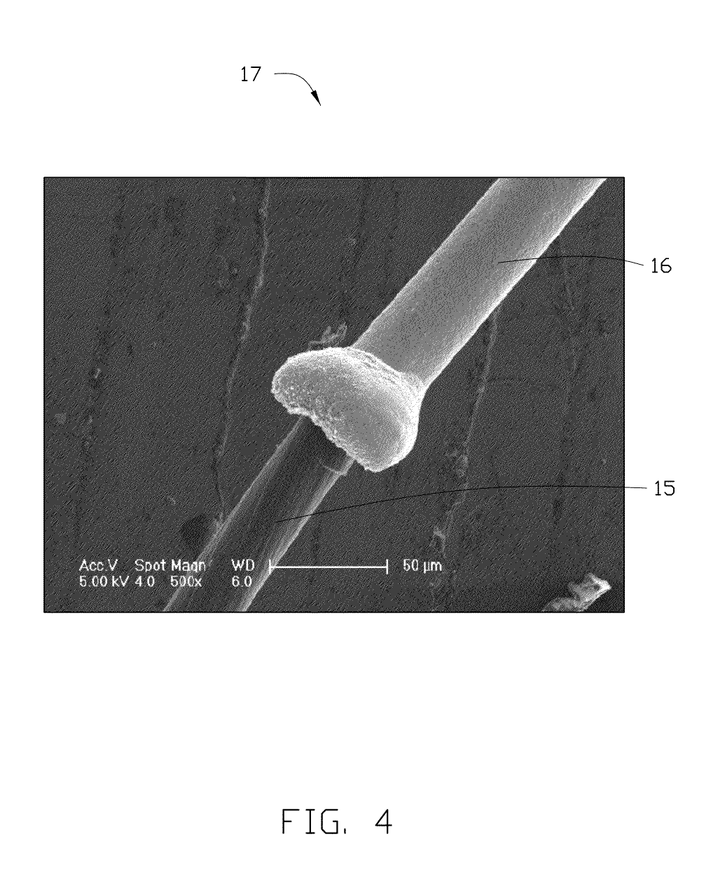

FIG. 4 illustrates in one embodiment, the carbon nanotube structure includes a plurality of carbon nanotube composite wires 17, the carbon nanotube composite wires 17 includes the twisted carbon nanotube wire 15 and a metal layer 16 coated on an outer surface of the carbon nanotube wire. A diameter of the twisted carbon nanotube wire 15 is about 25 micros. A twist of the twisted carbon nanotube wire 15 is about 100 r/cm.

The metal layer 16 can be formed on the outer surface of the twisted carbon nanotube wire 15 by a method such as plating, electroless plating, or vapor plating. Since the twisted carbon nanotube wire 15 has the smooth and dense surface, the metal layer 16 and the twisted carbon nanotube wire 15 can form a close bond, and the metal layer 16 is not easily detached from the twisted carbon nanotube wire 15. A material of the metal layer 16 can be can be selected from the group consisting of gold, silver, copper, molybdenum, and tungsten, other metals and their alloys having good electrical conductivity. In one embodiment, the diameter of the twisted carbon nanotube wire 15 ranges from about 1 micron to about 30 microns, the thickness of the metal layer 16 ranges from about 1 micron to about 5 microns, and the conductivity of the carbon nanotube composite wire 17 can reach 50 percent or more of the conductivity of the metal layer 16. Experiments show that when the thickness of the metal layer 16 ranges from about 1 micron to about 5 microns, the electrical conductivity of carbon nanotube composite wire 17 can be significantly improved in proportion to an increase of the diameter of the carbon nanotube composite wire 17; and the metal layer 16 is not be easily oxidized, the conductivity and service life of the carbon nanotube composite wire 17 can be increased. In one embodiment, the metal layer 16 is a copper layer, a thickness of the copper layer is about 5 micros; the conductivity of the carbon nanotube composite wire 17 is about 4.39×10⁷S/m, which is about 75% of a conductivity of copper.

FIG. 5 illustrates in one embodiment, the tensile strength of the carbon nanotube composite wire 17 is more than 900 MPa, which is about 9 times of the tensile strength of the gold wire of the same diameter.

When the carbon nanotube structure comprises the carbon nanotube wire and/or the carbon nanotube composite wire 17, the carbon nanotube wire and/or the carbon nanotube composite wire 17 can be braided or twisted together.

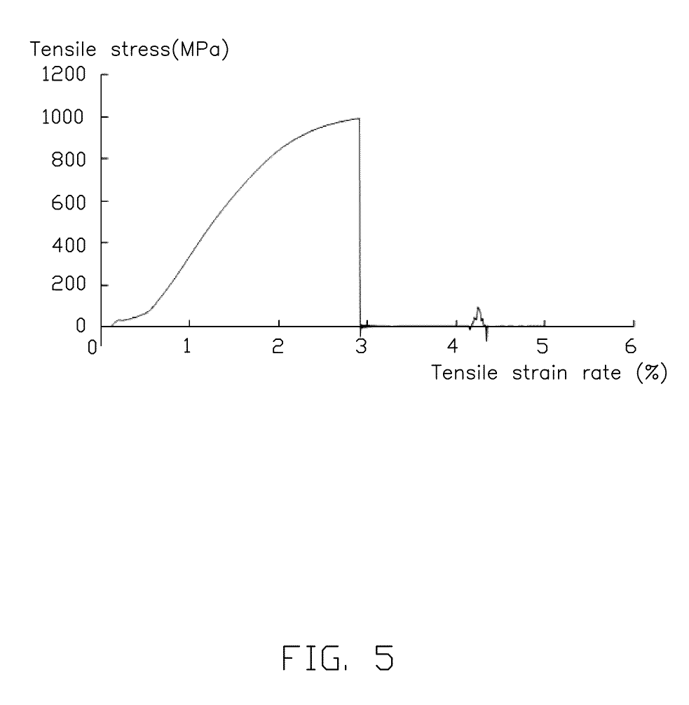

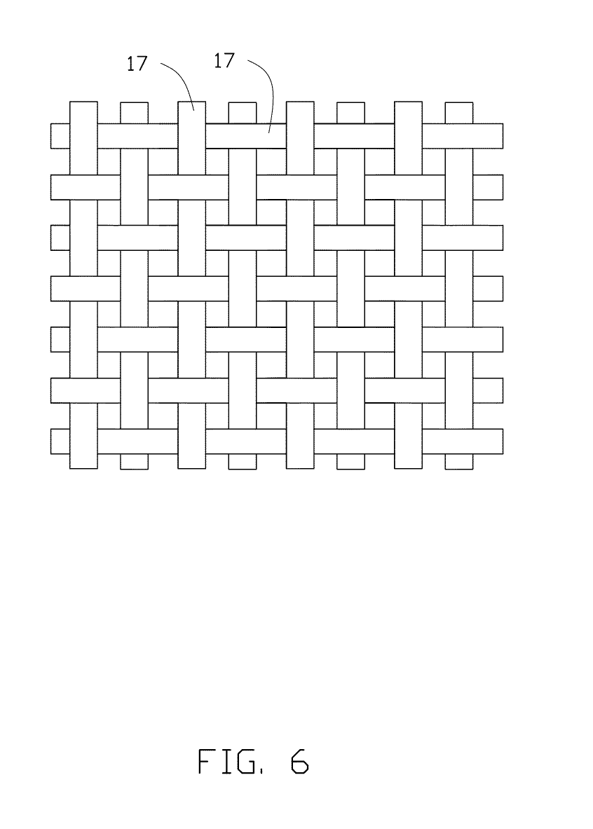

FIG. 6 illustrates in one embodiment, the shield layer 12 is a network structure formed by a plurality of carbon nanotube composite wires 17 braided together. Each of a horizontal direction and a vertical direction of the network structure includes a plurality of carbon nanotube composite wires 17. The plurality of carbon nanotube composite wires 17 in the horizontal direction are substantially parallel to and equally spaced from each other; and the plurality of carbon nanotube composite wires 17 in the vertical direction are substantially parallel to and equally spaced from each other. The plurality of carbon nanotube composite wires 17 in the horizontal direction intersect with the plurality of carbon nanotube composite wires 17 in the vertical direction. A mesh size of the network structure can be homogenized by controlling a space between the carbon nanotube composite wire 17 in the horizontal direction, and a space between the carbon nanotube composite wire 17 in the vertical direction; in order to make uniform the anti-radiation and anti-static properties of the shield layer 12. Additionally, the network structure includes a plurality of meshes, thereby increasing a permeability of the electromagnetic shielding material 100.

The carbon nanotube film can be a drawn carbon nanotube film, a flocculated carbon nanotube film or a pressed carbon nanotube film.

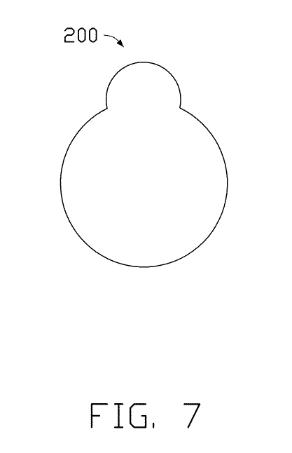

FIG. 7 illustrates the drawn carbon nanotube film includes a number of carbon nanotubes that are arranged substantially parallel to a surface of the drawn carbon nanotube film. A large number of the carbon nanotubes in the drawn carbon nanotube film can be oriented along a preferred orientation, meaning that a large number of the carbon nanotubes in the drawn carbon nanotube film are arranged substantially along the same direction. An end of one carbon nanotube is joined to another end of an adjacent carbon nanotube arranged substantially along the same direction, by van der Waals force, to form a free-standing film. The term ‘free-standing’ includes films that do not have to be supported by a substrate. The drawn carbon nanotube film can be formed by drawing from a carbon nanotube array. Examples of a drawn carbon nanotube film is taught by U.S. Pat. No. 7,045,108 to Jiang et al., and US patent application US 2008/0170982 to Zhang et al. A width of the drawn carbon nanotube film relates to the carbon nanotube array from which the drawn carbon nanotube film is drawn. A thickness of the carbon nanotube drawn film can range from about 0.5 nanometers to about 100 micrometers.

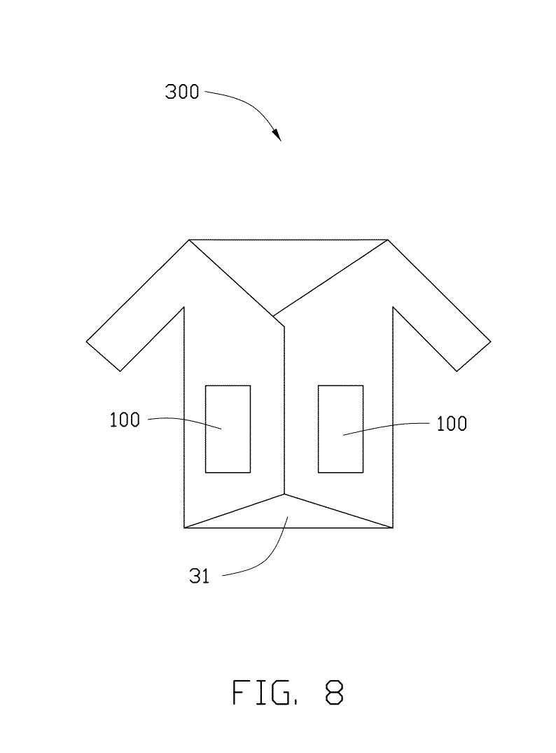

FIG. 8 illustrates the flocculated carbon nanotube film can include a number of carbon nanotubes entangled with each other. The carbon nanotubes can be substantially uniformly distributed in the flocculated carbon nanotube film. The flocculated carbon nanotube film can be formed by flocculating the carbon nanotube array. Examples of the flocculated carbon nanotube film are taught by U.S. Pat. No. 8,846,144 to Wang et al.

FIG. 9 illustrates the pressed carbon nanotube film can include a number of disordered carbon nanotubes arranged along a same direction or along different directions. Adjacent carbon nanotubes are attracted to each other and combined by van der Waals force. A planar pressure head can be used to press the carbon nanotubes array along a direction perpendicular to the substrate, a pressed carbon nanotube film having a plurality of isotropically arranged carbon nanotubes can be obtained. A roller-shaped pressure head can be used to press the carbon nanotubes array along a fixed direction, a pressed carbon nanotube film having a plurality of carbon nanotubes aligned along the fixed direction is obtained. The roller-shaped pressure head can also be used to press the array of carbon nanotubes along different directions, a pressed carbon nanotube film having a plurality of carbon nanotubes aligned along different directions is obtained. Examples of the pressed carbon nanotube film are taught by US PGPub. 20080299031A1 to Liu et al.

The carbon nanotube composite film can be formed by composite of the carbon nanotube film with metal, polymer, non-metallic or other materials. When the carbon nanotube composite film is formed by composite of the carbon nanotube film with a metal layer, the metal layer can be formed on the outer surface of the carbon nanotube film by a method such as plating, electroless plating, or vapor plating. A material of the metal layer can be selected from the group consisting of gold, silver, copper, and molybdenum tungsten, other metals and their alloys having good electrical conductivity.

The carbon nanotube structure can include at least two stacked carbon nanotube films and/or carbon nanotube composite films. The carbon nanotube structure can also include two or more coplanar carbon nanotube films and/or carbon nanotube composite films.

The electromagnetic shielding material 100 can also include a fabric layer 18. The shield layer 12 can be protected by the fabric layer 18 holding the shield layer 12 together with the substrate 11. A material of the fabric layer 18 can be the same as the material of the substrate 11. The fabric layer 18 is an optional component.

The fabric layer 18 and the shield layer 12 can be sewn together or bonded together with an adhesive.

The metal layer 16 has excellent oxidation resistance and durability due to the thickness of the metal layer ranges from 1 micron to 5 microns, which can improve the durability of the electromagnetic shielding material 100.

Because the thickness of the metal layer 16 ranges from 1 micron to 5 microns, when the carbon nanotube composite wire 17 is used, the metal layer 16 plays a major conductive role; because of a skin effect, the current is mostly transmitted through a surface of the carbon nanotube composite wire 17, that is, current is mostly transmitted under and through the metal layer 16. Thus, the conductivity of the carbon nanotube composite wire 17 is significantly increased, which can improve a work efficiency of the electromagnetic shielding material 100.

The carbon nanotube composite wire 17 has excellent mechanical properties, by optimizing the diameter and the twist of the twisted carbon nanotube wire 15; which can make the electromagnetic shielding material 100 have excellent bend resistance.

When the carbon nanotube composite wire 17 is used, the carbon nanotube wire cannot be easily broken due to the excellent mechanical properties of the carbon nanotube. Thus, the carbon nanotube composite wire 17 can maintain a closed circuit even if the metal layer 16 is broken. A durability of the carbon nanotube composite wire 17 can be improved.

The electromagnetic shielding material 100 can be applied to electromagnetic shielding clothing, such as apron, underwear, shirt, pants, and so on. The electromagnetic shielding clothing can be obtained by cutting out the electromagnetic shielding material 100 directly, or sewing the electromagnetic shielding material 100 between the clothing.

FIG. 10 illustrates an anti-radiation and anti-static apron 200 of a second embodiment. The anti-radiation and anti-static apron 200 is obtained by cutting out and sewing the electromagnetic shielding material 100 directly.

FIG. 11 illustrates an anti-radiation and anti-static shirt 300 of a third embodiment. The anti-radiation and anti-static shirt 300 includes the electromagnetic shielding material 100 and a shirt body 31. The electromagnetic shielding material 100 is sutured in the shirt body 31. The electromagnetic shielding material 100 can cover an entire or partial surface of the shirt body 31.

The shield layer of the electromagnetic shielding clothing includes a carbon nanotube structure. The carbon nanotube structure can form a conductive closed circuit due to the excellent conductivity of the carbon nanotubes. When partial carbon nanotubes of the conductive closed circuit cuts magnetic induction lines in a magnetic field, a magnetic flux of the conductive closed circuit will be changed, and an induction electromotive force and an induced current will be produced in the conductive closed circuit, thereby producing a reverse electromagnetic field for shielding the external magnetic field.

The carbon nanotube structure can produce the corona discharge to eliminate external charge. The carbon nanotube structure can also make the electrostatic charge discharge quickly by reducing the surface resistivity of the clothing. Therefore, an anti-radiation and anti-static effect of the clothing can be improved.

The electromagnetic shielding clothing has excellent bend resistance and very little weight due to the excellent mechanical properties and light weight of the carbon nanotube structure.

It is to be understood that the above-described embodiments are intended to illustrate rather than limit the present disclosure. Variations may be made to the embodiments without departing from the spirit of the present disclosure as claimed. Elements associated with any of the above embodiments are envisioned to be associated with any other embodiments. The above-described embodiments illustrate the scope of the present disclosure but do not restrict the scope of the present disclosure.

What is claimed is:

1. An electromagnetic shielding material comprising:
a substrate comprising at least one surface; and
a shield layer comprising a carbon nanotube composite wire, located on the at least one surface of the substrate,
wherein the carbon nanotube composite wire comprises a carbon nanotube wire and a metal layer coated on an outer surface of the carbon nanotube wire; the carbon nanotube wire comprises a plurality of carbon nanotubes spirally arranged along an axial direction of the carbon nanotube wire, a carbon nanotube wire twist ranges from about 10 r/cm to about 300 r/cm, and a carbon nanotube wire diameter ranges from about 1 micron to about 30 microns; and a metal layer thickness ranges from about 1 micron to 5 about microns.

2. The electromagnetic shielding material of claim 1, wherein the shield layer comprises a plurality of carbon nanotube composite wires braided or twisted together.

3. The electromagnetic shielding material of claim 1, wherein the carbon nanotube wire has an S twist or a Z twist.

4. The electromagnetic shielding material of claim 1, wherein the carbon nanotube wire diameter ranges from about 10 microns to about 20 microns, and the carbon nanotube wire twist ranges from about 200 r/cm to about 250 r/cm.

5. The electromagnetic shielding material of claim 1, wherein the carbon nanotube wire diameter ranges from about 25 microns to about 30 microns, and the carbon nanotube wire twist ranges from about 100 r/cm to about 150 r/cm.

6. The electromagnetic shielding material of claim 1, wherein a space between adjacent carbon nanotubes along a radial direction of the carbon nanotube wire is less than or equal to 10 nanometers.

7. The electromagnetic shielding material of claim 1, wherein a carbon nanotube composite wire tensile strain rate is less than or equal to 3%.

8. An electromagnetic shielding material comprising:
a substrate comprising at least one surface; and
a shield layer comprising a carbon nanotube structure, located on the at least one surface of the substrate,
wherein the carbon nanotube structure comprises a plurality of carbon nanotubes forming a conductive closed circuit.

9. The electromagnetic shielding material of claim 8, wherein the carbon nanotube structure comprises at least one of a carbon nanotube wire, a carbon nanotube composite wire, a carbon nanotube film, and a carbon nanotube composite film.

10. The electromagnetic shielding material of claim 9, wherein the carbon nanotube structure comprises a plurality of carbon nanotube composite wires braided or twisted together.

11. The electromagnetic shielding material of claim 9, wherein the carbon nanotube structure comprises at least one carbon nanotube wire and at least one carbon nanotube composite wire braided or twisted together.

12. The electromagnetic shielding material of claim 9, wherein the carbon nanotube composite wire comprises the carbon nanotube wire and a metal layer coated on an outer surface of the carbon nanotube wire; the carbon nanotube wire comprises the plurality of carbon nanotubes spirally arranged along an axial direction of the carbon nanotube wire, a carbon nanotube wire twist ranges from about 10 r/cm to about 300 r/cm, and a carbon nanotube wire diameter ranges from about 1 micron to about 30 microns; and a metal layer thickness ranges from about 1 micron to about 5 microns.

13. The electromagnetic shielding material of claim 12, wherein a carbon nanotube composite wire tensile strain rate is less than or equal to 3%.

14. The electromagnetic shielding material of claim 9, wherein the carbon nanotube composite wire is a composite of the carbon nanotube wire and a material selected from the group of metal and polymer; and the carbon nanotube composite film is a composite of the carbon nanotube film and a material selected from the group of metal and polymer.

15. An electromagnetic shielding clothing comprising:
an electromagnetic shielding material comprising:
a substrate comprising at least one surface; and
a shield layer comprising a carbon nanotube structure, located on the at least one surface of the substrate,
wherein the carbon nanotube structure comprises a plurality of carbon nanotubes forming a conductive closed circuit.

16. The electromagnetic shielding clothing of claim 15, wherein the carbon nanotube structure comprises at least one of a carbon nanotube wire, a carbon nanotube composite wire, a carbon nanotube film, and a carbon nanotube composite film.

17. The electromagnetic shielding clothing of claim 15, wherein the carbon nanotube structure comprises a carbon nanotube composite wire, and the carbon nanotube composite wire comprises a carbon nanotube wire and a metal layer coated on an outer surface of the carbon nanotube wire; the carbon nanotube wire comprises the plurality of carbon nanotubes spirally arranged along an axial direction of the carbon nanotube wire, a carbon nanotube wire twist ranges from about 10 r/cm to about 300 r/cm, and a carbon nanotube wire diameter ranges from about 1 micron to about 30 microns; and a metal layer thickness ranges from about 1 micron to about 5 microns.

18. The electromagnetic shielding clothing of claim 17, wherein a carbon nanotube composite wire tensile strain rate is less than or equal to 3%.
